(19) United States
(12) Patent Application Publication
(10) Pub. No.: US 2023/0411310 A1
(43) Pub. Date: Dec. 21, 2023

(54) SEMICONDUCTOR DEVICE INCLUDING A DUMMY POWER PAD AND A PAD PLACEMENT METHOD THEREOF

(71) Applicant: SAMSUNG ELECTRONICS CO., LTD., Suwon-si (KR)

(72) Inventors: Kim Min SIC, Suwon-si (KR); Jinhyeong KIM, Suwon-si (KR); Hak-Ryul KIM, Suwon-si (KR); Inyoung CHOI, Suwon-si (KR)

(21) Appl. No.: 18/080,024

(22) Filed: Dec. 13, 2022

(30) Foreign Application Priority Data
May 25, 2022 (KR) 10-2022-0064216

(51) Int. Cl. H01L 23/60; H01L 27/02

(52) U.S. Cl. CPC H01L 23/60; H01L 29/6681; H01L 27/0296; H01L 27/0292

(57) ABSTRACT

A semiconductor device includes: at least one signal pad including power metal rings and configured to exchange an input/output signal with an input/output circuit; and a dummy power pad disposed adjacent to the at least one signal pad, wherein the dummy power pad includes a first clamp circuit connected to at least one of the power metal rings.

### CROSS-REFERENCE TO RELATED APPLICATION

This application claims priority under 35 U.S.C. § 119 to Korean Patent Application No. 10-2022-0064216 filed on May 25, 2022, in the Korean Intellectual Property Office, the disclosure of which is incorporated by reference herein in its entirety.

### TECHNICAL FIELD

Embodiments of the inventive concept relate to a semiconductor device, and more particularly, to a semiconductor device having a dummy power pad and a pad arrangement method thereof.

### DISCUSSION OF RELATED ART

Various semiconductor integrated circuits are mounted in mobile devices or electronic devices. As semiconductor integrated circuits are miniaturized or highly integrated, enhanced protection against static electricity is required. A circuit for protecting a semiconductor chip or circuit from static electricity is generally referred to as an electrostatic discharge (ESD) circuit. An ESD refers to a discharge phenomenon caused by static electricity. For example, due to the buildup of static electricity, a sudden momentary flow of electric current between two electrically charged objects may result from contact. More specifically, ESD refers to a phenomenon in which a high voltage generated by an electrostatic phenomenon is discharged beyond the breakdown voltage of a circuit. When ESD occurs in a semiconductor device, it may damage parts of the device. For example, a high-voltage static electricity momentarily generated in an input/output pad connected to an input or output circuit of a semiconductor device may destroy part of a semiconductor device (e.g., a gate insulating layer of a metal-oxide-semiconductor (MOS) transistor).

In general, when an ESD event occurs, it is necessary to quickly bypass the overcurrent generated by the ESD to protect the internal circuit or semiconductor device. However, there is a limit to the amount of ESD protection provided by using only the bypass circuit in the input/output pad. In addition, a filler pad for connecting to a power ring may be located in the pad area where the input/output pads are not disposed. However, since the filler pad has no ESD protection performance, it may serve as a path for the overcurrent caused by ESD. Accordingly, there is a need for a low-cost and high-efficiency technology that provides greater ESD protection for an input/output pad in a semiconductor device.

### SUMMARY

Embodiments of the present inventive concept provide a semiconductor device having a pad arrangement that provides a high electrostatic discharge (ESD) protection function at a low cost without an additional circuit, and a pad arrangement method thereof.

An embodiment of the present inventive concept provides, a semiconductor device including: at least one signal pad including power metal rings and configured to exchange an input/output signal with an input/output circuit; and a dummy power pad disposed adjacent to the at least one signal pad, wherein the dummy power pad includes a first clamp circuit connected to at least one of the power metal rings.

An embodiment of the present inventive concept provides, a semiconductor device including: a core logic unit configured to receive a power and configured to receive and process an input signal to generate an output signal; signal pads configured to transmit the input signal to the core logic unit or output the output signal from the core logic unit to an outside of the semiconductor device; a power/ground pad configured to transfer the power provided from a power rail to the core logic unit; and a dummy power/ground pad disposed at a position of a filler pad, wherein the dummy power/ground pad does not function exchange the power, the input signal, and the output signal with the core logic unit.

An embodiment of the present inventive concept provides, a method of disposing pads for transmitting a power or a signal to an internal circuit of a semiconductor device, the method including: disposing power pads, ground pads, and signal pads in a die edge region of the semiconductor device; detecting positions of filler pads formed between the signal pads; and disposing a dummy power pad or a dummy ground pad at the positions of the filler pads, wherein the dummy power pad or the dummy ground pad includes a clamp circuit for electrostatic discharge protection.

### BRIEF DESCRIPTION OF THE FIGURES

The above and other features of the present inventive concept will become more apparent by describing in detail embodiments thereof with reference to the accompanying drawings.

FIG. 1 is a diagram showing a semiconductor device having an arrangement structure according to an embodiment of the present inventive concept.

FIG. 2 is a diagram showing a pad arrangement method according to an embodiment of the present inventive concept.

FIG. 3 is a diagram showing a pad arrangement method according to another embodiment of the present inventive concept.

FIG. 4 is a diagram showing a pad arrangement method according to another embodiment of the present inventive concept.

FIGS. 5A, 5B, 5C and 5D are diagrams illustrating the structure of a dummy power/ground pad of FIG. 2.

FIGS. 6A and 6B are diagrams showing the structure of a signal pad of FIG. 2.

FIG. 7 is a diagram showing a filler pad shown in FIG. 3.

FIG. 8 is a diagram for briefly explaining features of the pad arrangement of FIG. 2.

FIG. 9 is a diagram for explaining the features of the pad arrangement of FIG. 2.

FIG. 10 is a flowchart schematically illustrating a pad arrangement method according to an embodiment of the present inventive concept.

### DETAILED DESCRIPTION OF THE EMBODIMENTS

Hereinafter, embodiments of the present inventive concept will be described with reference to the accompanying drawings. In the following description, the same elements may be designated by the same reference numerals.

In the following description, the term “pad” or “cell” is an area for configuring and supporting a pad during layout design of a semiconductor chip. In other words, the power pad is a layout unit including components for transmitting power transmitted through a power metal ring to the internal core logic of the chip. Hereinafter, the pad will be used as a basic term to describe the features of the present inventive concept. The power pad and a ground pad may include a metal layer and a clamp circuit for electrostatic discharge (ESD) protection, a power ring, a signal ring, and the like. In addition, the signal pad may include a combination of a metal layer for input/output of signals and a diode for ESD protection.

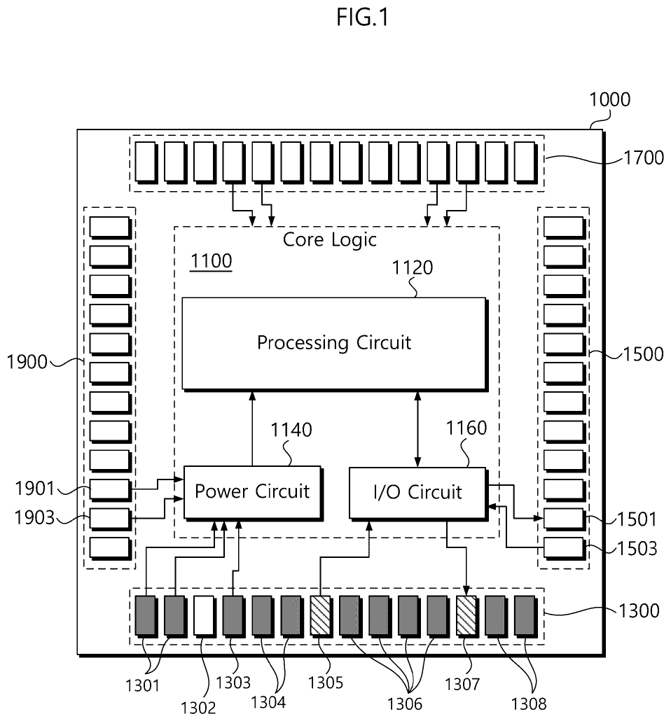

FIG. 1 shows a semiconductor device having an arrangement structure according to an embodiment of the present inventive concept. Referring to FIG. 1, a semiconductor device 1000 includes a core logic unit 1100 including a processing circuit 1120, a power circuit 1140, and an input/output circuit 1160, and pad arrays 1300, 1500, 1700, 1900. The pad arrays 1300, 1500, 1700, and 1900 may be disposed in an edge area of a chip die of the semiconductor device 1000. For example, the pad arrays 1300, 1500, 1700, and 1900 may surround the core logic unit 1100.

The processing circuit 1120 processes data using power provided from the power circuit 1140. The power circuit 1140 receives power supply voltages VDD, VSS, VDDO, and VSSO provided from outside the semiconductor device 1000. The processing circuit 1120 may process a command or data provided through the input/output circuit 1160, and may transmit data to the outside through the input/output circuit 1160.

The power circuit 1140 may regulate the received power supply voltage and provide the power supply voltage to various functional blocks of the core logic unit 1100 including the processing circuit 1120. According to the level of the power supply voltage, the power circuit 1140 may supply power to different power domains of the core logic unit 1100. The power circuit 1140 may receive the power supply voltages VDD, VSS, VDDO, and VSSO from power/ground pads 1301 and 1303 of the pad array 1300. The power supply voltages VDD, VSS, VDDO, and VSSO are provided through a power metal ring or ground metal ring having the form of a rail on upper or lower portions of the pad arrays 1300, 1500, 1700, and 1900. Then, the power supply voltages VDD, VSS, VDDO, and VSSO may be provided to the power circuit 1140 via the power/ground pads of the pad arrays 1300, 1500, 1700, and 1900.

The input/output circuit 1160 transfers externally provided data to the processing circuit 1120. The input/output circuit 1160 outputs data output from the processing circuit 1120 to the outside of the semiconductor device 1000. For example, the input/output circuit 1160 may include a data input buffer, an input driver, a data output buffer, an output driver, and an impedance matching circuit. The input/output circuit 1160 may receive data from the outside through a signal pad of the pad array 1300 or may output data to the outside.

The pad arrays 1300, 1500, 1700, and 1900 are disposed on a side or an edge area of the chip die of the semiconductor device 1000. The pad arrays 1300, 1500, 1700, and 1900 may be disposed in edge areas of one side, both sides, or four sides of the semiconductor device 1000. All circuits of the core logic unit 1100 may receive power or data through the pad arrays 1300, 1500, 1700, and 1900. In addition, data processed by the core logic unit 1100 may be output to the outside through the pad arrays 1300, 1500, 1700, and 1900. A function or characteristic of each of the pad arrays 1300, 1500, 1700, and 1900 is substantially the same. Accordingly, the characteristics of the pad arrays 1300, 1500, 1700, and 1900 of the present inventive concept will be described by describing only the characteristics of the pad array 1300 arranged in the lower edge area.

The pad array 1300 includes power/ground pads 1301 and 1303 that transmit power to the power circuit 1140. The power/ground pads 1301 and 1303 may be connected to the power circuit 1140 or an internal circuit, and may transmit power supply voltages VDD, VSS, VDDO, and VSSO. In particular, the power/ground pads 1301 and 1303 include a clamp circuit having an ESD protection function. The clamp circuit may discharge a charge that induces a high voltage when an ESD event occurs. The clamp circuit provides ESD protection by discharging a large amount of charge to a power metal ring carrying a supply voltage (e.g., VDD or VDDO) or a ground metal ring carrying a ground voltage (e.g., VSS or VSSO).

In addition, the pad array 1300 includes signal pads 1305 and 1307 for transmitting an externally provided signal to an internal circuit or an internally generated signal to the outside. The signal pads 1305 and 1307 include diodes connected between a pad to which a signal is input or output and a power supply voltage VDD, VSS, VDDO, and VSSO. When an ESD event occurs, these diodes divert to the power metal ring or ground metal ring for voltages that exceed the turn-on voltage.

In addition, the pad array 1300 includes dummy pads 1304, 1306, and 1308 that do not transmit power or signals into the semiconductor device 1000. Since these pads do not have an electrical connection with the core logic unit 1100, they will be referred to as dummy pads hereinafter. When designing the layout of the semiconductor device 1000, filler pads for automatically arranging only power metal rings at the positions of the dummy pads where there is no exchange of signals or power with the core logic unit 1100 are inserted. For example, a filler pad 1302 disposed between the power/ground pads 1301 and 1303 that provides power to the power circuit 1140 corresponds to this case. However, the addition of these filler pads without ESD protection does not contribute to enhancing the ESD protection capability of the semiconductor device 1000.

According to an embodiment of the present inventive concept, each of the dummy pads 1304, 1306, and 1308 may be formed of the power/ground pad having a clamp circuit. In particular, the dummy pads 1304, 1306, and 1308 disposed adjacent to or around the signal pads 1305 and 1307 may be disposed as power/ground pads. However, the dummy pads at positions where only the power pads 1301, 1303 are present may be formed of the filler pad 1302. For convenience of design, not only the dummy pads 1304, 1306, 1308 positioned around the signal pads 1305, 1307 but also all of the filler and dummy pads 1302, 1304, 1306, and 1308 can be formed as a power/ground pad. Hereinafter, these power/ground pads 1302, 1304, 1306, and 1308 that do not have a power transmission function will be referred to as a dummy power pad D_PP or a dummy ground pad D_GP.

Here, the power/ground pad may be classified in detail according to the type of voltage to be supplied. For example, a power pad that supplies the power supply voltage VDD is called a first power pad, and a ground pad that supplies the ground voltage VSS is called a first ground pad. In addition, the power pad that supplies the input/output power supply voltage VDDO, which is a relatively high voltage, is called a second power pad, and the ground pad that supplies the input/output ground voltage VSSO is called a second ground pad. The power/ground pads described above each include a clamp circuit for ESD protection. In addition, the dummy power/ground pads also include the clamp circuit. On the other hand, the dummy power/ground pads have the same configuration as the power/ground pads, but do not deliver power.

According to the method of forming the pad of the semiconductor device 1000 of the present inventive concept, a dummy power/ground pad having no function of transmitting a signal or power to the core logic unit 1100 may be disposed in place of the filler pad. In particular, dummy pads positioned adjacent to or around a signal pad requiring an ESD protection function may be disposed as dummy power/ground pads including a clamp circuit. In this case, high ESD protection may be provided to the core logic unit 1100 or the signal pads of the semiconductor device 1000.

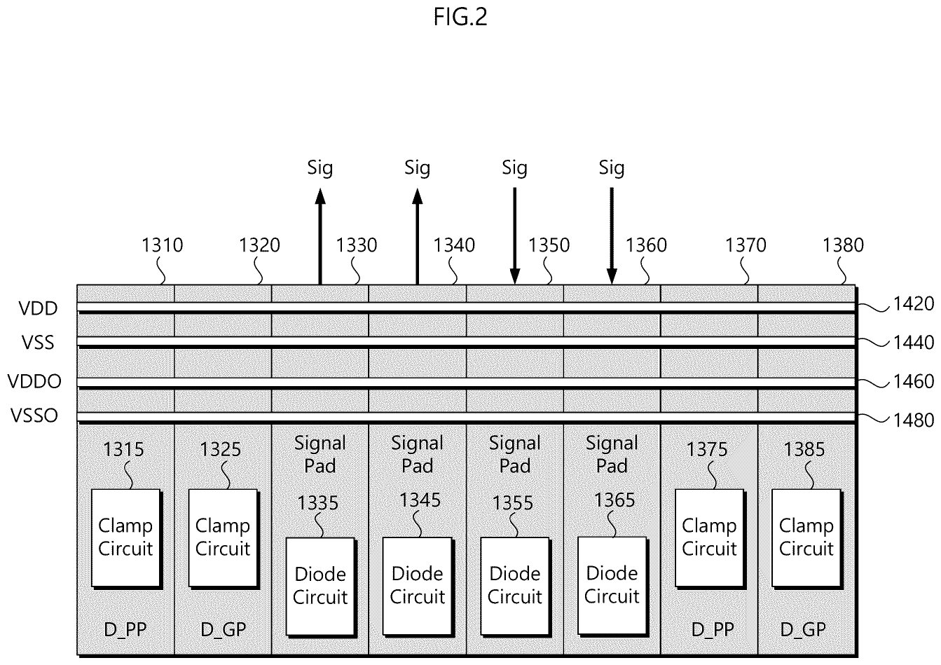

FIG. 2 is a diagram showing a pad arrangement method according to an embodiment of the present inventive concept. Referring to FIG. 2, all of the dummy pads in contact with the signal pads 1330, 1340, 1350, and 1360 or located within a specific distance from the signal pads 1330, 1340, 1350, 1360 may be disposed as dummy power/ground pads 1310, 1320, 1370, 1380.

Each of the signal pads 1330, 1340, 1350, and 1360 transmits an externally provided signal to the core logic unit 1100 and a signal output from the core logic unit 1100 to the outside. Each of the signal pads 1330, 1340, 1350, and 1360 includes diode circuits 1335, 1345, 1355, 1365 for ESD protection. For example, in the case of the signal pad 1330, a first diode is connected to an input pad to which a signal is input and a second power metal ring 1460 for supplying the input/output power voltage VDDO, and a second diode connected between the input pad and a second ground metal ring 1480. The diode circuits 1345, 1355, and 1365 of each of the remaining signal pads 1340, 1350, and 1360 may be configured substantially the same as the diode circuit 1335 of the signal pad 1330.

When an ESD event occurs, the diode circuits 1335, 1345, 1355, and 1365 transfer the input ESD to a first power metal ring 1420 for supplying the power supply voltage VDD or the second power metal ring 1460 for supplying the input/output power supply voltage VDDO. However, the function of discharging the introduced charge is performed in the clamp circuit. The clamp circuit of the power pad or dummy power pad closest to the signal pad where the ESD event occurred is responsible for the electrostatic discharge. In other words, since the signal pad and the power pad or the dummy power pad are closer to each other, the resistance of the power metal ring decreases and the ESD efficiency increases. For this reason, to enhance the ESD protection function, the dummy power pad, not a filler pad, is disposed at positions adjacent to the signal pads 1330, 1340, 1350, and 1360.

The dummy power/ground pads (D_PP or D_GP) 1310, 1320, 1370, and 1380 may perform an ESD function through clamp circuits 1315, 1325, 1375, and 1385. For example, when an ESD event occurs in the signal pad 1360, the clamp circuit 1375 of the adjacent dummy power pad 1370 may perform ESD. In other words, when an ESD is generated from the signal pad 1360 to the first power metal ring 1420 through the diode circuit, the clamp circuit 1375 constituting the discharge path having the lowest resistance may operate. Charges of the first power metal ring 1420 may be discharged to a first ground metal ring 1440 by the clamp circuit 1375. Here, the dummy power pad D_PP and the dummy ground pad D_GP are arranged in pairs. ESD protection performance of the power metal rings 1420, 1440, 1460, and 1480 may be increased through the configuration of the dummy power/ground pad pair D_PP/D_GP.

According to the present inventive concept, when the dummy power/ground pad is disposed at the position of the dummy pad where the filler pad is disposed, the ESD protection function for the signal pad may be enhanced. In the past, the filler pad only played a role of connecting the power metal rings 1420, 1440, 1460 and 1480. However, when the dummy power/ground pad is disposed at a location of a filler pad adjacent to or close to the signal pad area, ESD efficiency may be increased. Therefore, the present inventive concept can improve the ESD protection capability for the signal pad.

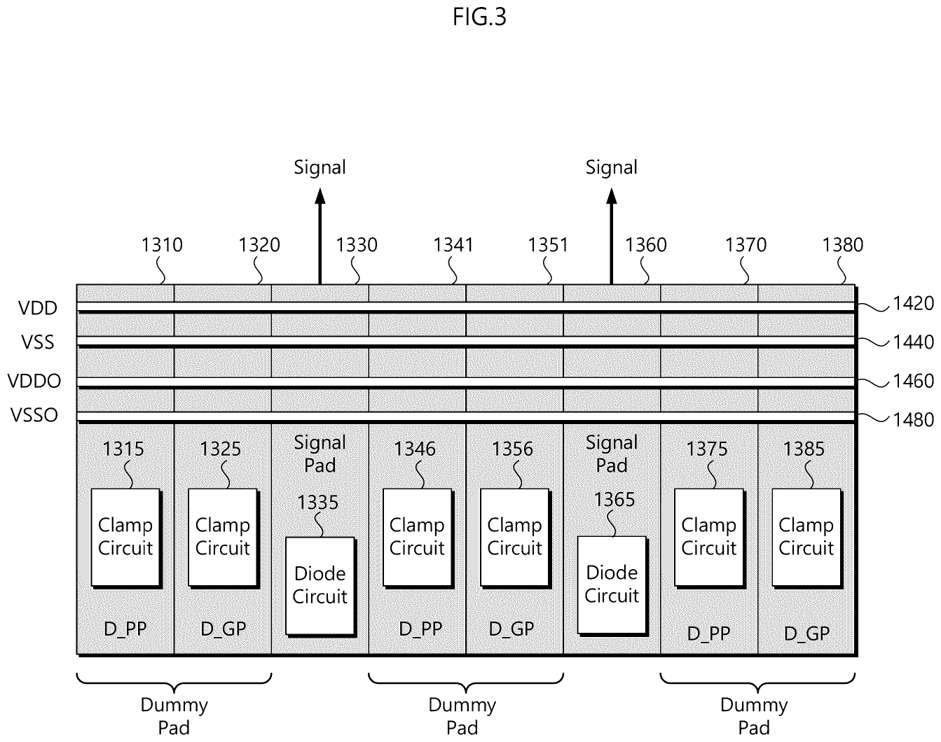

FIG. 3 is a diagram showing a pad arrangement method according to another embodiment of the present inventive concept. Referring to FIG. 3, all of the dummy pads adjacent to the signal pads 1330 and 1360 may be formed as the dummy power/ground pads 1310, 1320, 1341, 1351, 1370 and 1380.

Each of the signal pads 1330 and 1360 transmits an externally provided signal to the core logic unit 1100 or a signal from the core logic unit 1100 to the outside. Each of the signal pads 1330 and 1360 includes diode circuits 1335 and 1365 for ESD protection.

When an ESD event occurs, the diode circuits 1335 and 1365 transfer a large amount of electrostatic charge to the first power metal ring 1420 for supplying the power supply voltage VDD or the second power metal ring 1460 for supplying the input/output power supply voltage VDDO. However, the function of discharging the introduced charge is performed in the clamp circuit. For example, the clamp circuit of the dummy power/ground pad closest to the signal pad where the ESD event occurred is responsible for the ESD. In other words, since the signal pad and the dummy power/ground pad are closer to each other, the resistance of the power metal ring decreases and the ESD efficiency increases. For this reason, to strengthen the ESD protection function, a dummy power/ground pad, not a filler pad, is disposed at positions adjacent to the signal pads 1330 and 1360.

The dummy power/ground pads 1310, 1320, 1341, 1351, 1370, and 1380 may perform an ESD function through the clamp circuits 1315, 1325, 1346, 1356, 1375 and 1385. For example, when an ESD event occurs in the signal pad 1360, the clamp circuit 1375 of the adjacent dummy power pad 1370 may perform ESD. In other words, when an ESD is generated from the signal pad 1360 to the first power metal ring 1420 through the diode circuit, the clamp circuit 1375 constituting the discharge path having the lowest resistance may operate. Charges of the first power metal ring 1420 may be discharged to the first ground metal ring 1440 by the clamp circuit 1375.

According to the present inventive concept, when the dummy power/ground pad is disposed at the position of the dummy pad that uses the filler pad, the ESD protection function for the signal pad can be strengthened. In the past, the filler pad only played a role of connecting the power metal rings 1420, 1440, 1460, 1480. However, when the dummy power/ground pad is disposed at a position of the filler pad adjacent to or close to the signal pad, the ESD protection ability for the signal pad may be improved by increasing the ESD efficiency by the clamp circuit.

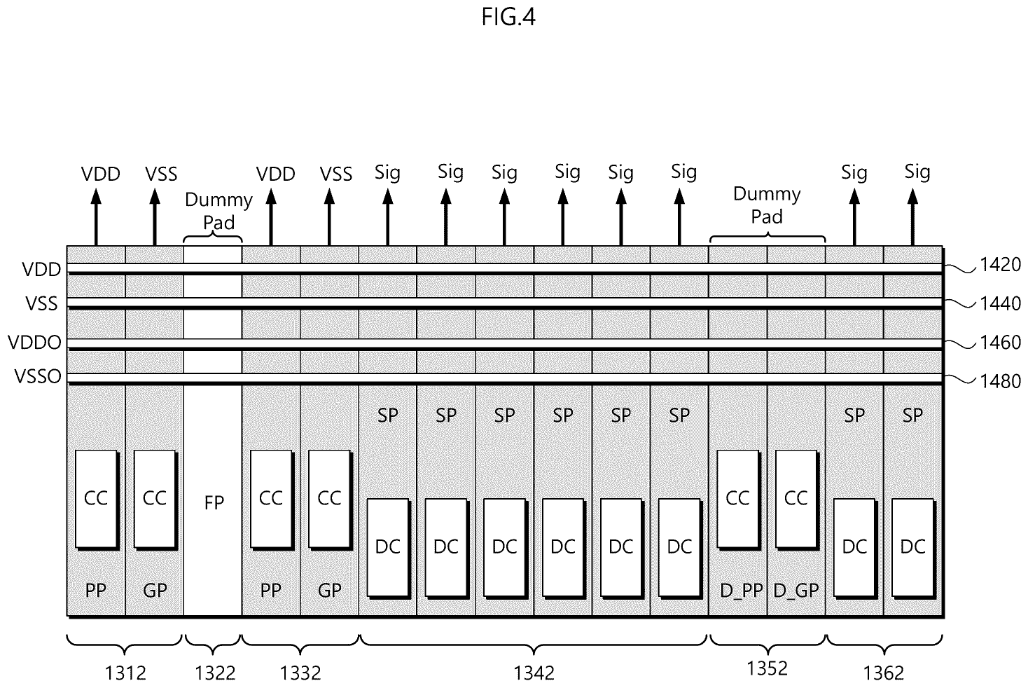

FIG. 4 is a diagram showing a pad arrangement method according to another embodiment of the present inventive concept. Referring to FIG. 4, a filler pad may be disposed on a position of dummy pad between the power/ground pads 1312 and 1332. In addition, dummy pads located adjacent to the signal pads 1342 and 1362 may be assigned as the power/ground pad 1352. In the power/ground pad 1352, a dummy power pad D_PP and a dummy ground pad D_GP may be inserted in a pair.

Each of the signal pads 1342 and 1362 transmits an externally provided signal Sig to the core logic unit 1100. Each of the signal pads 1342 and 1362 includes a diode circuit (hereinafter, DC) for ESD protection.

When an ESD event occurs, the diode circuits DC transfer the introduced electrostatic charge to the first power metal ring 1420 for supplying the power supply voltage VDD or the second power metal ring 1460 for supplying the input/output power supply voltage VDDO. However, the function of discharging the introduced charge is performed by the clamp circuit CC of any one of the power/ground pads 1312, 1332 and 1352. For example, the clamp circuit CC of the power/ground pad closest to the signal pad where the ESD event occurred will be in charge of ESD. In other words, since the signal pad and the power/ground pad are closer to each other, the resistance of the power metal ring decreases and the ESD efficiency increases. For this reason, to enhance the ESD protection function, the dummy pads 1352, not a filler pad, are disposed at positions adjacent to the signal pads 1342, 1362.

The structure of the dummy power/ground pad 1352 is substantially the same as the power/ground pads 1312 and 1332. However, the dummy power/ground pads 1352 does not have a function of supplying power to the core logic unit 1100 or the semiconductor device 1000. The dummy power/ground pad 1352 may provide power to the internal circuit when the power domain of the internal circuit is the same as that of the corresponding power/ground pad 1352. However, when the power domain of the internal circuit is different from the corresponding power/ground pad 1352, power supply may not be performed. The function of the dummy power/ground pad 1352 is to perform an ESD function through the clamp circuits CC. For example, when an ESD event occurs in the signal pad 1362, the clamp circuit CC provided in the dummy power pad D_PP of the adjacent dummy/ground power pad 1352 may perform ESD. In other words, when an ESD occurs from the signal pad 1362 to the first power metal ring 1420 through the diode circuit, the clamp circuit CC constituting the discharge path having the lowest resistance may operate. Charges of the first power metal ring 1420 may be discharged to the first ground metal ring 1440 by the clamp circuit CC.

According to an embodiment of the present inventive concept, a dummy pad positioned between the power/ground pads 1312 and 1332 may be disposed as a filler pad FP. However, in the case of a dummy pad adjacent to or adjacent to the signal pads 1342 and 1362, a dummy power/ground pad may be disposed. In this case, the ESD protection function for the signal pads 1342 and 1362 may be strengthened by the clamp circuit provided in the dummy power/ground pad.

It has been described that the dummy pad positioned between the power/ground pads 1312 and 1332 may be disposed as the filler pad 1322. However, it will be well understood that all dummy pads may be allocated as dummy power/ground pads instead of the filler pads FP for ease and simplification of design. When the dummy power/ground pad is disposed at a position of the dummy pad that utilizes the conventional filler pad FP, the ESD protection function for the signal pad SP may be strengthened. The filler pad FP only served to connect the power metal rings 1420, 1440, 1460, and 1480 between the adjacent power/ground pads 1312 and 1332. However, when the dummy power/ground pad is disposed instead of the filler pad FP, the ESD protection ability for the signal pad SP may be improved by increasing the ESD performance.

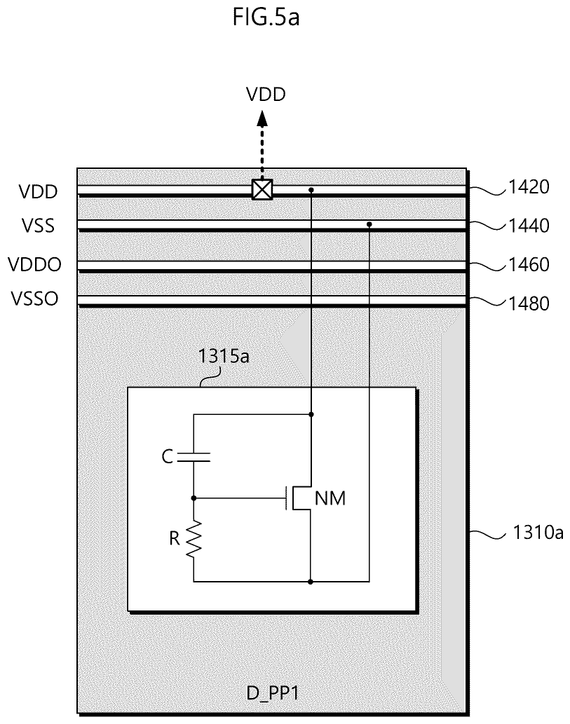

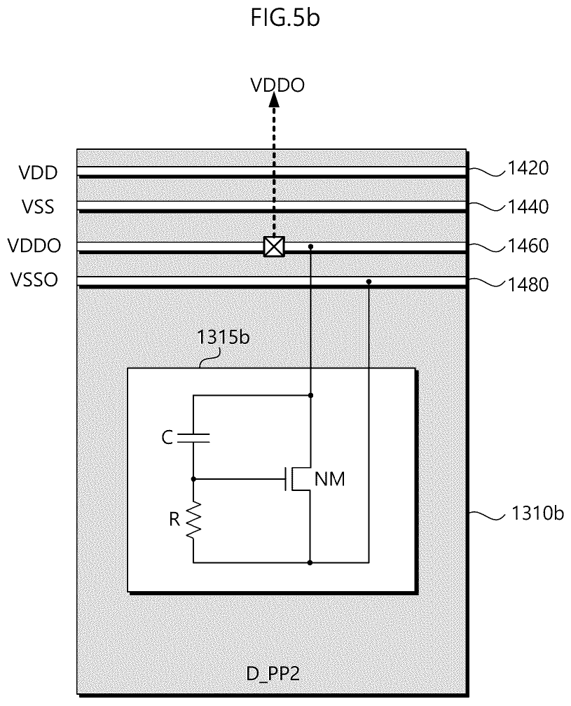

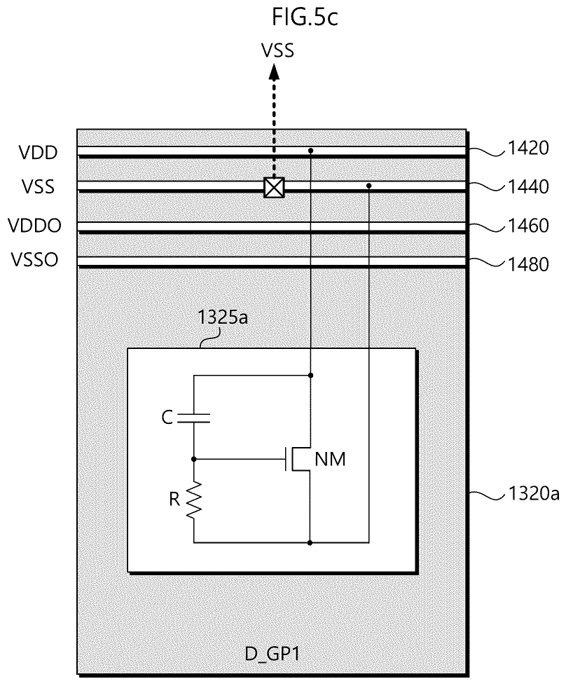

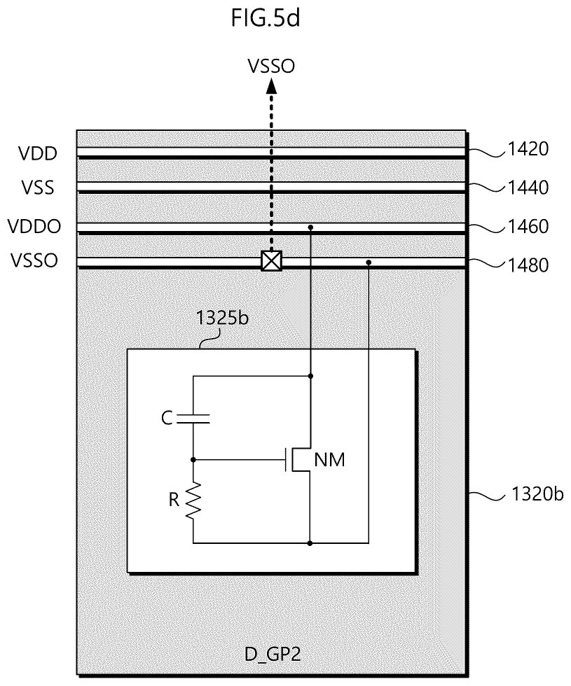

FIGS. 5A to 5D are diagrams illustrating the structure of the dummy power/ground pad of FIG. 2. In general, the power/ground pad is classified according to the type of power supply voltages VDD, VSS, VDDO and VSSO provided to the core logic unit 1100.

The dummy power/ground pad of the present inventive concept may be classified to a first dummy power pad (D_PP1), a second dummy power pad (D_PP2), a first dummy ground pad (D_GP1) and a second dummy ground pad D_GP2. FIG. 5A and FIG. 5B show the structures of the first and second dummy power pads D_PP1 and D_PP2, and FIG. 5C and FIG. 5D show the structures of the first and second dummy ground pads D_GP1 and D_GP2.

Referring to FIG. 5A, the first dummy power pad 1310a includes power metal rings 1420, 1440, 1460 and 1480 and a clamp circuit 1315a. The first dummy power pad 1310a has substantially the same structure as a power pad for transferring the power supply voltage VDD to the core logic unit 1100. However, the function of transferring the power supply voltage VDD to the inside of the first dummy power pad 1310a is not essential. When the internal circuit corresponds to the power domain of the power supply voltage VDD, the first dummy power pad 1310a may supply the power supply voltage VDD. However, when the internal circuit corresponds to the power domain different from the power supply voltage VDD, the first dummy power pad 1310a may not supply the power supply voltage VDD. In this case, the first dummy power pad 1310a has only a static discharge protection function by the clamp circuit 1315a without a power supply function.

The clamp circuit 1315a is respectively connected to the first power metal ring 1420 that supplies the power supply voltage VDD and the first ground metal ring 1440 that supplies the ground voltage VSS. The clamp circuit 1315a may include, for example, a capacitor C, a resistor R, and a transistor NM. The clamp circuit 1315a operates to clamp a voltage difference corresponding to a predetermined power supply voltage VDD and a ground voltage VSS. It will be understood that the clamp circuit 1315a may further include a means for increasing ESD detection performance, such as a Schmitt-trigger, at the gate terminal of the transistor NM.

When the power supply voltage VDD rises sharply, the transistor NM is turned on by the impulse voltage applied to the resistor R of the clamp circuit 1315a. In particular, when an ESD event occurs, the charge flowing into the first power metal ring 1420 for supplying the power supply voltage VDD is transferred to the resistor R by the capacitor C, and the voltage across the resistor R will rise. When the voltage across the resistor R is equal to or greater than the threshold voltage of the transistor NM, the transistor NM is turned on. Then, charges of the first power metal ring 1420 are discharged to the first ground metal ring 1440. For example, the turned-on transistor NM passes the charges of the first power metal ring 1420 to the first ground metal ring 1440. In this way, the semiconductor device 1100 may be protected from the ESD impact generated between the first power metal ring 1420 and the first ground metal ring 1440 by the clamp circuit 1315a.

Referring to FIG. 5B, the second dummy power pad 1310b includes power metal rings 1420, 1440, 1460 and 1480 and a clamp circuit 1315b. The second dummy power pad 1310b has the same structure as a power pad for transferring the input/output power supply voltage VDDO to the core logic unit 1100. However, the function of transferring the input/output power supply voltage VDDO to the inside of the second dummy power pad 1310b is not essential. When the internal circuit corresponds to the power domain of the power supply voltage VDDO, the second dummy power pad 1310b may supply the power supply voltage VDDO. However, when the internal circuit corresponds to the power domain different from the power supply voltage VDDO, the second dummy power pad 1310b may not supply the power supply voltage VDDO. In this case, the second dummy power pad 1310b has only a static discharge protection function by the clamp circuit 1315b without a power supply function.

The clamp circuit 1315b is respectively connected to the second power metal ring 1460 supplying the input/output power supply voltage VDDO and the second ground metal ring 1480 supplying the input/output ground voltage VSSO. The clamp circuit 1315b may include a capacitor C, a resistor R, and a transistor NM. The clamp circuit 1315b operates to clamp the second power metal ring 1460 and the second ground metal ring 1480 with a voltage corresponding to the voltage difference between the predetermined input/output power supply voltage VDDO and the input/output ground voltage VSSO. The clamp circuit 1315b may further include a means for adjusting the switching level of the transistor NM, such as a Schmitt-trigger, at the gate terminal of the transistor NM.

When the input/output power supply voltage VDDO sharply increases, the transistor NM is turned on by the impulse voltage applied to the resistor R of the clamp circuit 1315b. In particular, when an ESD event occurs, the charge flowing into the second power metal ring 1460 for supplying the input/output power supply voltage VDDO is transferred to the resistor R by the capacitor C, and voltage will rise. When the voltage across the resistor R becomes equal to or greater than the threshold voltage of the transistor NM, the transistor NM is turned on. Then, charges of the second power metal ring 1460 are discharged to the second ground metal ring 1480. For example, the turned-on transistor NM passes the charges of the second power metal ring 1460 to the second ground metal ring 1480. In this way, the semiconductor device 1100 may be protected from the ESD impact generated between the second power metal ring 1460 and the second ground metal ring 1480 by the clamp circuit 1315b.

Referring to FIG. 5C, the first dummy ground pad 1320a includes power metal rings 1420, 1440, 1460 and 1480 and a clamp circuit 1325a. The first dummy ground pad 1320a has the same structure as the ground pad for transferring the ground voltage VSS to the core logic unit 1100. However, the function of transferring the ground voltage VSS to the inside of the first dummy ground pad 1320a is not essential. When the internal circuit corresponds to the power domain of the ground voltage VSS, the first dummy ground pad 1320a may supply the ground voltage VSS. However, when the internal circuit has a power domain different from the ground voltage VSS, the first dummy ground pad 1320a may not supply the ground voltage VSS. In this case, the first dummy ground pad 1320a has only a static discharge protection function by the clamp circuit 1325a without a power supply function.

The clamp circuit 1325a is respectively connected to the first power metal ring 1420 that supplies the power supply voltage VDD and the first ground metal ring 1440 that supplies the ground voltage VSS. The clamp circuit 1325a may include a capacitor C, a resistor R, and a transistor NM. The clamp circuit 1325a operates to clamp a voltage difference corresponding to a predetermined power supply voltage VDD and a ground voltage VSS. The clamp circuit 1325a may further include a means for adjusting the switching level of the transistor NM, such as a Schmitt-trigger, at the gate terminal of the transistor NM.

When the power supply voltage VDD rapidly increases, the transistor NM is turned on by the impulse voltage applied to the resistor R of the clamp circuit 1325a. In particular, when an ESD event occurs, the charge flowing into the first power metal ring 1420 for supplying the power supply voltage VDD is transferred to the resistor R by the capacitor C, and the voltage across the resistor R will rise. When the voltage across the resistor R are equal to or greater than the threshold voltage of the transistor NM, the transistor NM is turned on. Then, charges of the first power metal ring 1420 are discharged to the first ground metal ring 1440. In this way, the semiconductor device 1100 may be protected from the ESD impact generated between the first power metal ring 1420 and the first ground metal ring 1440 by the clamp circuit 1325a.

Referring to FIG. 5D, the second dummy ground pad 1320b includes power metal rings 1420, 1440, 1460, and 1480 and a clamp circuit 1325b. The second dummy ground pad 1320b has the same structure as a ground pad for transferring the input/output ground voltage VSSO to the core logic unit 1100. However, the function of transferring the input/output ground voltage VSSO to the inside of the second dummy ground pad 1320b is not essential. When the internal circuit corresponds to the power domain of the input/output ground voltage VSSO, the second dummy ground pad 1320b may supply the input/output ground voltage VSSO. However, when the internal circuit corresponds to a power domain different from the input/output ground voltage VSSO, the second dummy ground pad 1320b may not supply the input/output ground voltage VSSO. In this case, the second dummy ground pad 1320b has only a static discharge protection function by the clamp circuit 1325b without a power supply function.

The clamp circuit 1325b is respectively connected to the second power metal ring 1460 supplying the input/output power supply voltage VDDO and the second ground metal ring 1480 supplying the input/output ground voltage VSSO. The clamp circuit 1325b may include a capacitor C, a resistor R, and a transistor NM. The clamp circuit 1325b operates to clamp the second power metal ring 1460 and the second ground metal ring 1480 with a voltage corresponding to the voltage difference between the predetermined input/output power supply voltage VDDO and the input/output ground voltage VSSO. The clamp circuit 1325b may further include a means for adjusting the switching level of the transistor NM, such as a Schmitt-trigger, at the gate terminal of the transistor NM.

When the input/output power supply voltage VDDO sharply increases, the transistor NM is turned on by the impulse voltage applied to the resistor R of the clamp circuit 1325b. In particular, when an ESD event occurs, the charge flowing into the second power metal ring 1460 for supplying the input/output power supply voltage VDDO is transferred to the resistor R by the capacitor C, and the voltage across the resistor R will rise. When the voltage across the resistor R becomes equal to or greater than the threshold voltage of the transistor NM, the transistor NM is turned on. Then, charges of the second power metal ring 1460 are discharged to the second ground metal ring 1480. In this way, the semiconductor device 1100 may be protected from the ESD impact generated between the second power metal ring 1460 and the second ground metal ring 1480 by the clamp circuit 1325b.

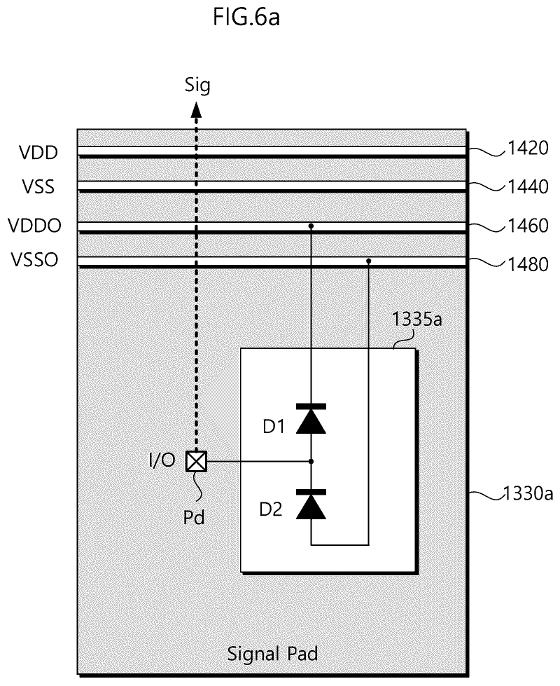

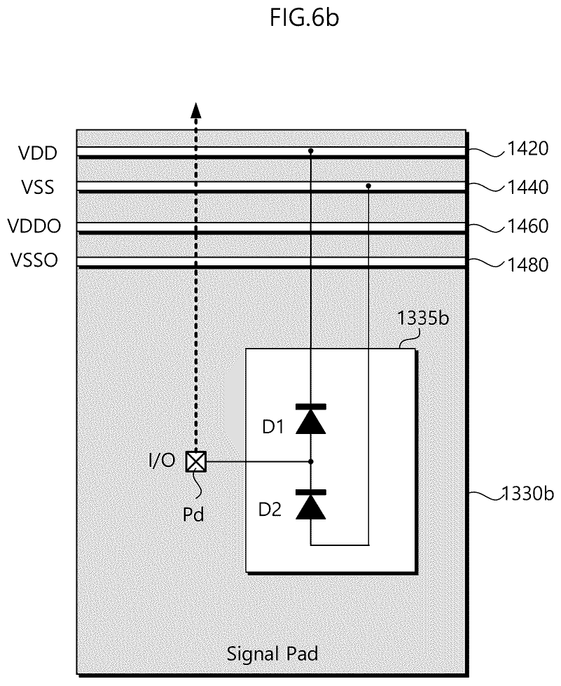

FIGS. 6A and 6B are diagrams showing the structure of the signal pad of FIG. 2. FIG. 6A shows a signal pad 1330a using an input/output power supply voltage VDDO and an input/output ground voltage VSSO, and FIG. 6B shows a signal pad 1330b using a power supply voltage VDD and a ground voltage VSS, respectively.

Referring to FIG. 6A, the signal pad 1330a includes power metal rings 1420, 1440, 1460, and 1480 and a diode circuit 1335a. The signal pad 1330a transfers the input signal Sig to the core logic unit 1100. To accomplish this, the signal pad 1330a may include a pad Pd or a contact for transmitting the input signal Sig to the core logic unit 1100.

The diode circuit 1335a may be connected between the second power metal ring 1460 and the second ground metal ring 1480. The second ground metal ring 1480 is connected to the anode of the second diode D2, and the cathode of the second diode D2 is connected to the anode of the first diode D1. A cathode of the first diode D1 is connected to the second power metal ring 1460. In particular, the pad Pd to which the input signal Sig is provided is connected to the anode of the first diode D1 and the cathode of the second diode D2.

When an ESD occurs through the pad Pd to which the input signal Sig is transmitted, any one of the first and second diodes D1 and D2 is turned on. In addition, charges introduced through the clamp circuit of the dummy power pad disposed at the closest position through the second power metal ring 1460 or the second ground metal ring 1480 may be discharged. For example, when an ESD in which a large amount of positive charge is introduced through the pad Pd occurs, the first diode D1 connected in the forward direction is turned on. In addition, the introduced positive charges may be discharged by a clamp circuit of a nearest power/ground pad or a dummy power/ground pad through the second power metal ring 1460. In this way, the signal pad 1330a can be protected even when an ESD event occurs.

Referring to FIG. 6B, the signal pad 1330b includes power metal rings 1420, 1440, 1460 and 1480 and a diode circuit 1335b. The signal pad 1330b transfers the input signal Sig to the core logic unit 1100. To accomplish this, the signal pad 1330b may include a pad Pd or a contact for transmitting the input signal Sig to the core logic unit 1100.

The diode circuit 1335b may be connected between the first power metal ring 1420 and the first ground metal ring 1440. The first ground metal ring 1440 is connected to the anode of the second diode D2, and the cathode of the second diode D2 is connected to the anode of the first diode D1. A cathode of the first diode D1 is connected to the first power metal ring 1420. In particular, the pad Pd to which the input signal Sig is provided is connected to the anode of the first diode D1 or the cathode of the second diode D2.

When an ESD occurs through the pad Pd to which the input signal Sig is transmitted, any one of the first and second diodes D1 and D2 is turned on. In addition, the charge introduced through the clamp circuit of the dummy power/ground pad disposed at the closest position through the first power metal ring 1420 or the first ground metal ring 1440 may be discharged. For example, when an ESD in which a large amount of positive charge is introduced through the pad Pd occurs, the first diode D1 connected in the forward direction is turned on. In addition, the introduced positive charges may be discharged by the clamp circuit of the nearest power/ground pad or the dummy power/ground pad through the first power metal ring 1420. When a large amount of negative charge is introduced through the pad Pd, the second diode D2 is turned on, and the pad Pd is electrically connected to the first ground metal ring 1440. In addition, the introduced negative charge may be discharged by the clamp circuit of the nearest power/ground pad or the dummy power/ground pad.

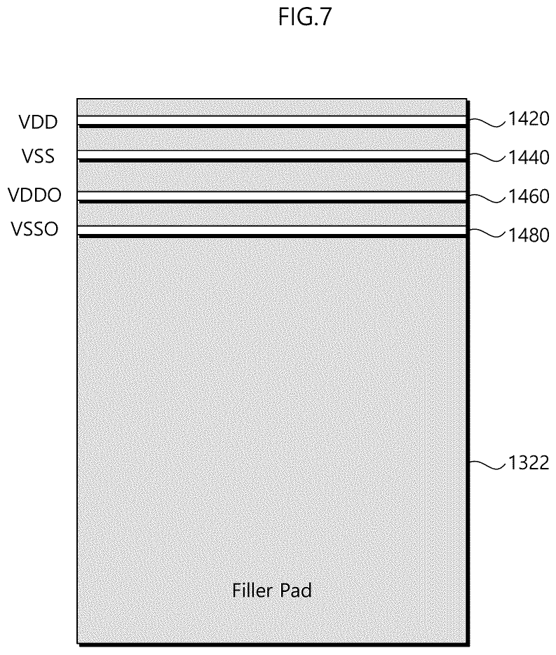

FIG. 7 is a diagram showing the filler pad shown in FIG. 3. Referring to FIG. 7, the filler pad 1322 includes power metal rings 1420, 1440, 1460 and 1480.

The filler pad 1322 is simply used to fill an empty area between the power/ground pad or the signal pad. When designing a layout, the power metal rings 1420, 1440, 1460, and 1480 may be connected to neighboring power/ground pads or signal pads only by inserting the filler pad 1322. The filler pad 1322 does not have a circuit or configuration for supporting a separate ESD protection function. Accordingly, in the case of the semiconductor device 1100 requiring enhanced ESD protection, the dummy power pads 1310a and 1310b or the dummy ground pads 1320a and 1320b may be disposed.

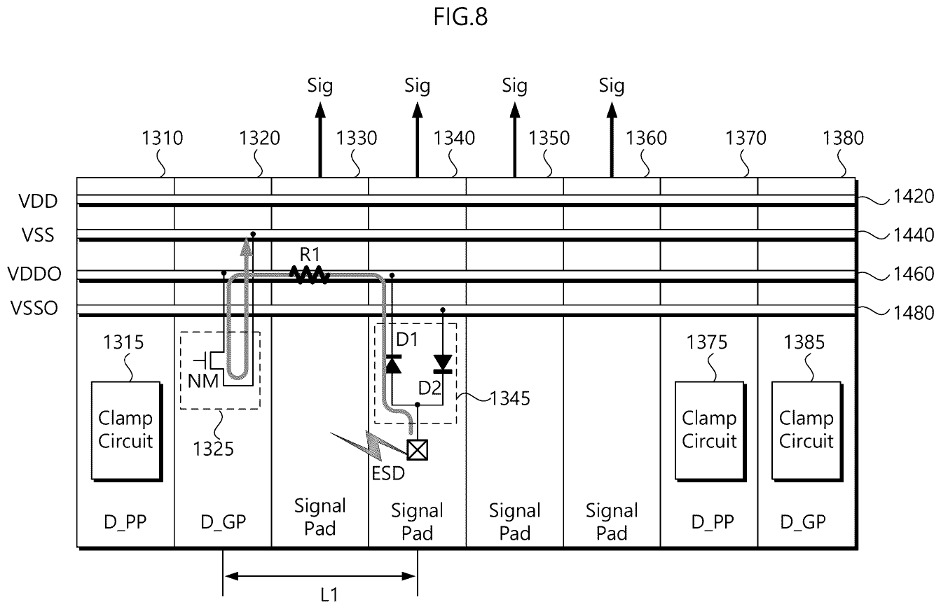

FIG. 8 is a diagram for briefly explaining the features of the present inventive concept in the pad arrangement of FIG. 2. Referring to FIG. 8, it is assumed that an ESD event occurs in one of the signal pads 1330, 1340, 1350 and 1360. For example, it is assumed that ESD zapping occurs in the signal pad 1340 and instantaneous voltage stress occurs.

The diode circuit 1345 of the signal pad 1340 connects the second power metal ring 1460 providing the input/output power supply voltage VDDO and the second ground metal ring 1480 providing the input/output ground voltage VSSO. Accordingly, the first diode D1 connected in the forward direction by ESD zapping is turned on and the charges are transferred to the second power metal ring 1460. In addition, the charge transferred to the second power metal ring 1460 is discharged to the first ground metal ring 1440 through the clamp circuit 1325 of the dummy ground pad 1320 located at the closest distance L1 to the signal pad 1340.

If the dummy power pads 1310 and 1370 or the dummy ground pads 1320 and 1380 are filler pads, a large amount of charge flowing into the signal pad 1340 is discharged through the remote power pad or ground pad. In this case, the semiconductor device 1100 or the internal circuit may not receive sufficient ESD protection. However, the ESD protection performance of the semiconductor device 1100 may be enhanced by disposing the dummy power pad adjacent to or near the signal pad.

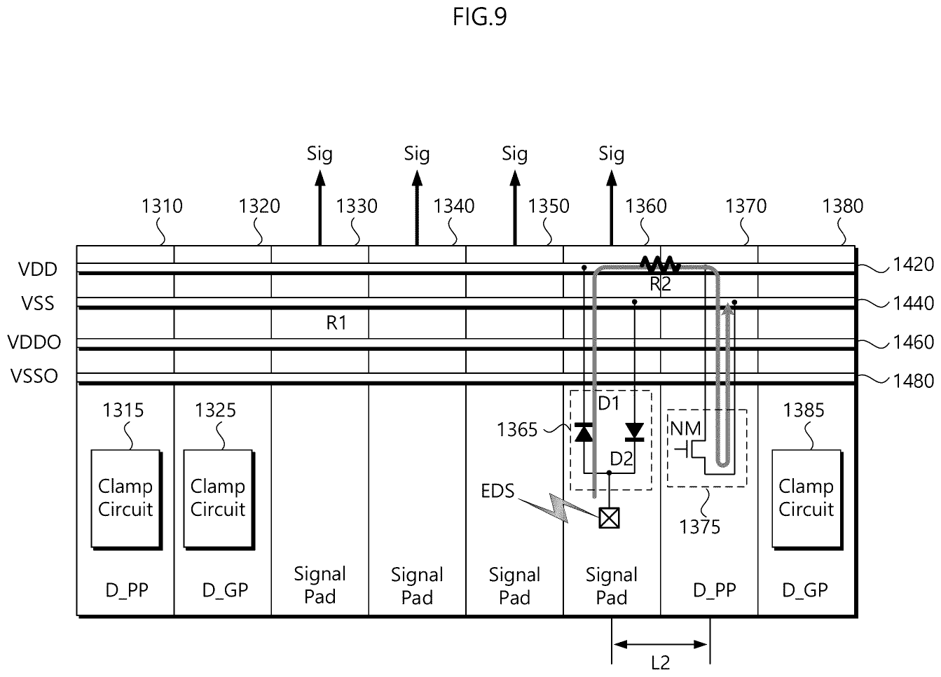

FIG. 9 is a diagram for explaining the features of the present inventive concept in the pad arrangement of FIG. 2. Referring to FIG. 9, assume that an ESD event on a signal pad 1360 having a diode circuit 1365 connected to a first power metal ring 1420 and a first ground metal ring 1440 has occurred. For example, it is assumed that ESD zapping occurs in the signal pad 1360 and instantaneous voltage stress occurs.

The diode circuit 1365 of the signal pad 1360 connects the first power metal ring 1420 providing the power supply voltage VDD and the first ground metal ring 1440 providing the ground voltage VSS. Accordingly, the first diode D1 connected in the forward direction by ESD zapping is turned on, and a large amount of charge is transferred to the first power metal ring 1420. In addition, the electric charge can be discharged from the first power metal ring 1420 by being transferred to the first ground metal ring 1440 through the clamp circuit 1375 of the dummy power pad 1370 located closest to the signal pad 1360.

If the dummy power pads 1310 and 1370 or the dummy ground pads 1320 and 1380 are filler pads, a large amount of electric charge flowing into the signal pad 1360 is discharged through a power pad or ground pad that is more distant from the signal pad 1360. In this case, the semiconductor device 1100 or the internal circuit may not receive sufficient ESD protection. However, the ESD protection performance of the semiconductor device 1100 may be enhanced by disposing the dummy power pad 1370 at the position of the filler pad adjacent to the signal pad 1360.

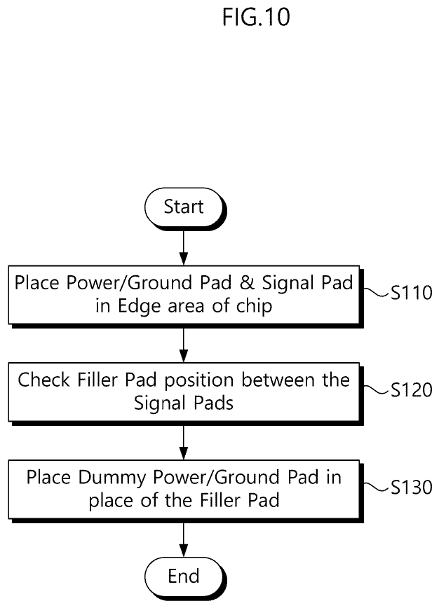

FIG. 10 is a flowchart schematically illustrating a pad arrangement method according to an embodiment of the present inventive concept. Referring to FIG. 1 and FIG. 10, a dummy power/ground pad having a clamp circuit may be formed at positions of the filler pads in the pad array 1300 of the semiconductor device 1000.

In step S110, power pads, ground pads, and signal pads for transferring the power supply voltage and the input/output signal to the core logic unit 1100 are disposed. These pads may be disposed in a die edge area of the semiconductor device 1000.

In step S120, positions of signal pads having electrical connection with the core logic unit 1100 or filler pads formed between power/ground pads are detected. A filler pad may be disposed between the power pads, the ground pads, and the signal pads for the purpose of connecting to the power metal ring.

In step S130, a dummy power pad or a dummy ground pad is disposed at positions of the detected filler pads. The dummy power pad and the dummy ground pad do not provide a power supply voltage or a ground voltage to the core logic unit 1100, but include a clamp circuit.

According to the pad arrangement method described above, the ESD protection performance of the semiconductor device 1100 may be enhanced by disposing the dummy power/ground pad at the position of the filler pad adjacent to the signal pad.

While the present inventive concept has been described with reference to embodiments thereof, it will be apparent to those of ordinary skill in the art that various changes and modifications may be made thereto without departing from the spirit and scope of the present inventive concept as set forth in the following claims.

What is claimed is:

1. A semiconductor device, comprising:
at least one signal pad comprising power metal rings and configured to exchange an input/output signal with an input/output circuit; and
a dummy power pad disposed adjacent to the at least one signal pad,
wherein the dummy power pad includes a first clamp circuit connected to at least one of the power metal rings.

2. The device of claim 1, wherein the power metal rings comprises:
a first power metal ring for providing a power supply voltage;
a first ground metal ring for providing a ground voltage;
a second power metal ring for providing an input/output power supply voltage; and
a second ground metal ring for providing an input/output ground voltage.

3. The device of claim 2, wherein the first clamp circuit comprises:
a transistor having a first end connected to the first power metal ring or the second power metal ring;
a capacitor connected between the first end of the transistor and a gate of the transistor; and
a resistor connected to the gate of the transistor and the first ground metal ring or the second ground metal ring.

4. The device of claim 2, wherein the signal pad includes a diode circuit connected to one of the first power metal ring and the second power metal ring and one of the first ground metal ring and the second ground metal ring.

5. The device of claim 4, wherein the diode circuit comprises:
a first diode having a cathode connected to the first power metal ring or the second power metal ring; and
a second diode having an anode connected to the first ground metal ring or the second ground metal ring,
wherein the anode of the first diode is connected to a cathode of the second diode.

6. The device of claim 1, further comprising:
a dummy ground pad disposed adjacent to the at least one signal pad.

7. The device of claim 6, wherein the dummy ground pad includes a second clamp circuit connected to at least one of the power metal rings.

8. The device of claim 7, wherein the dummy power pad and the dummy ground pad are disposed in pairs.

9. A semiconductor device, comprising:
a core logic unit configured to receive a power and configured to receive and process an input signal to generate an output signal;
signal pads configured to transmit the input signal to the core logic unit or output the output signal from the core logic unit to an outside of the semiconductor device;
a power/ground pad configured to transfer the power provided from a power rail to the core logic unit; and
a dummy power/ground pad disposed at a position of a filler pad, wherein the dummy power/ground pad does not function exchange the power, the input signal, and the output signal with the core logic unit.

10. The device of claim 9, wherein the power rail includes a plurality of power metal rings.

11. The device of claim 10, wherein the plurality of power metal rings comprises:
a first power metal ring for providing a power supply voltage;
a first ground metal ring for providing a ground voltage;
a second power metal ring for providing an input/output power supply voltage; and
a second ground metal ring for providing an input/output ground voltage.

12. The device of claim 11, wherein the dummy power/ground pad is connected to two of the plurality of power metal rings and includes a clamp circuit.

13. The device of claim 12, wherein the clamp circuit comprises:
a transistor having a first end connected to the first power metal ring or the second power metal ring;
a capacitor connected between the first end of the transistor and a gate of the transistor; and
a resistor connecting the gate of the transistor to the first ground metal ring or the second ground metal ring.

14. The device of claim 11, wherein the signal pad includes a diode circuit connected to one of the first power metal ring and the second power metal ring and connected to one of the first ground metal ring and the second ground metal ring.

15. The device of claim 14, wherein the diode circuit comprises:
a first diode having a cathode connected to the first power metal ring or the second power metal ring, and an anode connected to a signal input pad; and
a second diode having an anode connected to the first ground metal ring or the second ground metal ring, and a cathode connected to the signal input pad.

16. The device of claim 9, wherein the dummy power/ground pad is disposed adjacent to the signal pads.

17. A method of disposing pads for transmitting a power or a signal to an internal circuit of a semiconductor device, the method comprising:
disposing power pads, ground pads, and signal pads in a die edge region of the semiconductor device;
detecting positions of filler pads formed between the signal pads; and
disposing a dummy power pad or a dummy ground pad at the positions of the filler pads,
wherein the dummy power pad or the dummy ground pad includes a clamp circuit for electrostatic discharge protection.

18. The method of claim 17, wherein the clamp circuit discharges electrostatic charge flowing into any one of the signal pads to at least one of power metal rings supplying a power supply voltage, a ground voltage, an input/output power supply voltage, and an input/output ground voltage.

19. The method of claim 18, wherein the dummy power pad or the dummy ground pad does not have a connection path for supplying at least one of the power supply voltage, the ground voltage, the input/output power supply voltage, and the input/output ground voltage to the internal circuit.

20. The method of claim 17, further comprising:
disposing the dummy power pad or the dummy ground pad at positions of filler pads positioned between the power pads and the ground pads.
